(19) United States
(12) Patent Application Publication
(10) Pub. No.: US 2005/0136628 A1
(43) Pub. Date: Jun. 23, 2005

(54) Method for implanting ions in semiconductor process and method for fabricating semiconductor device using the same

(76) Inventors: Seung Woo Jin, Kyoungki-do (KR); Bong Soo Kim, Seoul (KR); Kyoung Bong Rouh, Kyoungki-do (KR)

Correspondence Address: LADAS & PARRY LLP, 224 SOUTH MICHIGAN AVENUE, SUITE 1200, CHICAGO, IL, 60604, US

(21) Appl. No.: 10/889,704

(22) Filed: Jul. 13, 2004

(30) Foreign Application Priority Data
Dec. 23, 2003 (KR) 2003-95549

(51) Int. Cl. H01L 21/425

(52) U.S. Cl. 438/515

(57) ABSTRACT

Disclosed are a method for implanting ions in a semiconductor process and a method for fabricating semiconductor devices using the same. The method for implanting ions comprises steps of: providing a semiconductor substrate; and implanting BF impurities or mixed BF₂ and B₁₁, impurities into the semiconductor substrate. The mixed BF₂ and B₁₁ impurities may be sequentially implanted, in the order of BF₂ first and B₁₁ second or in the order of B₁₁ first and BF₂ second, into the semiconductor substrate. If the ion implantation as described above is applied to a process for fabricating semiconductor devices, it is expected that refresh and cell current properties of semiconductor devices can be enhanced.

### BACKGROUND OF THE INVENTION

1. Field of the Invention

The present invention relates to a method for implanting ions in a semiconductor process, and more particularly to a method for implanting ions for suppressing punch-through or controlling threshold voltage (Vt) into a semiconductor substrate in order to improve refresh and cell current properties of semiconductor devices.

2. Description of the Prior Art

In general, ion implantation for controlling threshold voltage (Vt) is executed for MOS transistors in order to secure threshold voltage (Vt). For example, for NMOS transistors, implantation of ions for controlling threshold voltage is executed using p-type impurities. If drain voltage is relatively low in short channel MOS transistors, a depletion layer does not directly extend to a source side within a semiconductor substrate. However, because the surface of such a semiconductor substrate is somewhat depleted, the height of a potential barrier adjacent to the source may be varied by the drain voltage. This is called as surface punch-through; implantation of ions for controlling threshold voltage will increase interface concentration between a semiconductor substrate and a gate oxide film, thereby providing not only an effect of controlling threshold voltage but also an effect of suppressing surface punch-through.

Therefore, in order to control threshold voltage and suppress punch-through, mainly either B₁₁ or BF₂ is selected as p-type impurities when implanting ions for controlling threshold voltage.

Here, If B₁₁ is implanted as impurities to be implanted when fabricating semiconductors having fine patterns of today, it is needed to control energy required for ion implantation somewhat low, and to control dosage of the impurities somewhat high due to diffusion. If B₁₁ is applied to ion implantation in this manner, there is a problem in that the refresh property of semiconductor devices is deteriorated as the energy and dosage for ion implantation are controlled.

Accordingly, recently, BF₂ is selected as impurities in lieu of B₁₁. If BF₂ is employed for ion implantation, the energy for ion implantation can be readily controlled, and the dosage of impurities can be reduced as an effect of F₁₉ that suppresses diffusion of B₁₁. However, leakage current can be produced due to disadvantages that current decreases and F₁₉ and B₁₁ are combined as an effect of F₁₉. In addition, deterioration of gate oxide integration (GOI) property due to F₁₉ may be caused.

### SUMMARY OF THE INVENTION

Accordingly, the present invention has been made to solve the above-mentioned problems occurring in the prior art, and an object of the present invention is to provide a method for implanting ions in a semiconductor process in order to improve a refresh property of a semiconductor device.

Another object of the present invention is to provide a method for fabricating a semiconductor with an improved refresh property through controlling ion implantation.

According to an aspect of the present invention, there is provided a method for implanting ions comprising the steps of: providing a semiconductor substrate; and implanting BF impurities or mixed BF₂ and B₁₁ impurities into the semiconductor substrate.

According to another aspect of the present invention, there is provided a method for fabricating a semiconductor device comprising the steps of: providing a semiconductor substrate; and implanting BF impurities or mixed BF₂ and B₁₁ impurities into a cell area in the semiconductor substrate, thereby forming an area for controlling threshold voltage of the cell area.

According to another aspect of the present invention, there is also provided a method for fabricating a semiconductor device comprising steps of: providing a semiconductor substrate; and implanting BF impurities or mixed BF₂ and B₁₁ impurities into a PMOS transistor area in the semiconductor substrate, thereby forming an area for controlling threshold voltage of the PMOS transistor.

Still, according to the present invention, there is also provided a method for fabricating a semiconductor device comprising steps of: providing a semiconductor substrate; and implanting BF impurities or mixed BF₂ and B₁₁ impurities into an NMOS transistor area in the semiconductor substrate, thereby forming an area for controlling threshold voltage of the NMOS transistor.

Here, it is preferred that the BF impurities are controlled to have a mass of 29 to 30 amu (atomic mass unit) and are implanted in a dosage of 1.0E11 to 1.0E16 dose/cm² with energy of 1 to 100 KeV. In order to avoid a channeling effect, it is possible to execute the ion implantation in a state in which the semiconductor is tilted to about 60° at the maximum.

In addition, with the mixed BF₂ and B₁₁ impurities, it is preferable to sequentially implant BF₂ and B₁₁, in this order, or to implant B₁₁ and BF₂, in this order, into the semiconductor substrate.

In particular, according to the present invention, BF impurities or mixed BF₂ and B₁₁ impurities are readily applied to ion implantation into a cell area, a PMOS area of a PMOS transistor, an NMOS area of a NMOS transistor, etc.

According to the present invention, a BF mixture or a mixture of BF₂ and B₁₁ is employed as impurities in implantation of ions for threshold voltage in lieu of B₁₁ or BF₂ which has been conventionally used for that purpose. Accordingly, it is possible to sufficiently reduce F₁₉ generated during ion implantation. If the F₁₉ is sufficiently reduced, diffusion of B₁₁ can be suppressed, the gate oxide integration (GOI) property can be enhanced, and the disadvantage caused by the combination of F₁₉ and B₁₁ can be improved. Therefore, if the ion implantation according to the present invention is implemented in fabricating semiconductor devices, it is possible to enhance refresh and cell current properties of semiconductor devices. Furthermore, the present invention has an advantage in that the ion implantation can be executed without modifying existence apparatus.

### BRIEF DESCRIPTION OF THE DRAWINGS

The above and other objects, features and advantages of the present invention will be more apparent from the following detailed description taken in conjunction with the accompanying drawings, in which:

FIG. 1 is a cross-sectional view for illustrating the inventive method for implanting ions in a semiconductor process; and

FIG. 2 is a graph indicating contact resistance measured when the inventive method for implanting ions is employed.

### DETAILED DESCRIPTION OF THE PREFERRED EMBODIMENTS

Hereinafter, a preferred embodiment of the present invention will be described with reference to the accompanying drawings.

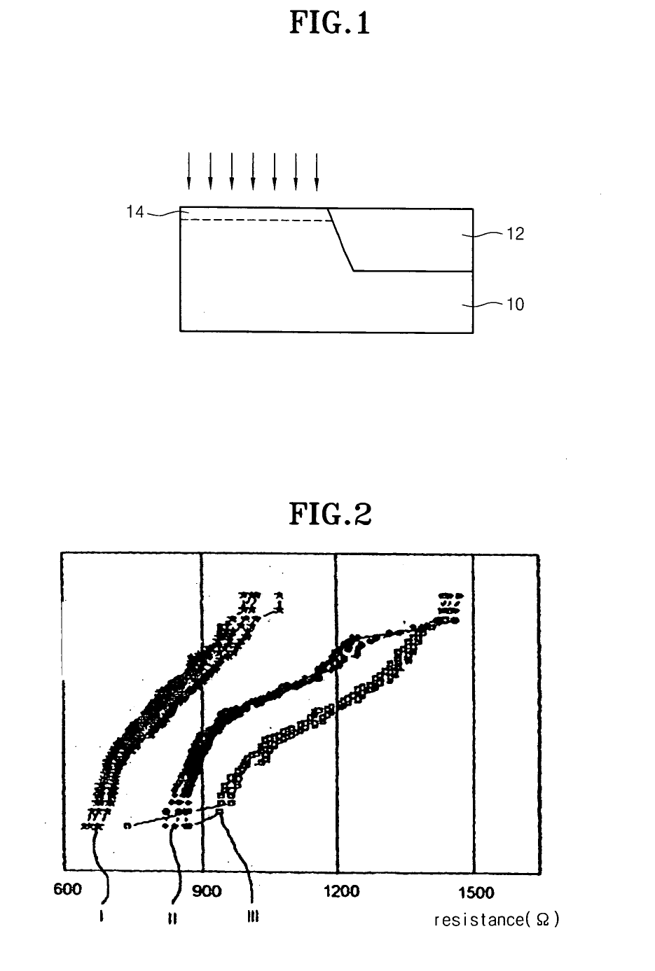

FIG. 1 is a cross-sectional view for illustrating the inventive method for implanting ions in a semiconductor process.

Referring to FIG. 1, a semiconductor substrate 10 is provided. Herein, the semiconductor substrate 10 is divided into an active area and a non-active area by a device isolation film. The device isolation film 12 is preferably a trench device isolation film appropriate for implementing a fine pattern. Subsequently, ion implantation is executed, thus forming an ion implantation area 14, into which BF impurities are implanted. In particular, the ion implantation is executed under the condition in which ion energy is adjusted to about 50 KeV and dosage is adjusted to about 1.0E14 dose/cm². More particularly, the ion implantation may be executed under the condition in which the ion energy is adjusted to not more than about 50 KeV and the dosage is adjusted to not more than 1.0E14 dose/cm².

Implantation of ions for controlling threshold voltage can be executed by implanting BF impurities into a semiconductor substrate through ion implantation as described above; therefore, it is possible to increase interface concentration between a semiconductor substrate and a gate oxide film, thereby making it possible not only to control threshold voltage but also to suppress punch-through.

In addition, it is possible to select mixed BF₂ and B₁₁ impurities in lieu of BF impurities. If mixed BF₂ and B₁₁ impurities are selected, it is preferred that BF₂ is firstly implanted into the semiconductor substrate and then B₁₁ is subsequently implanted into the semiconductor substrate. Furthermore, it is also preferred that that B₁₁ is firstly implanted into the semiconductor substrate and then BF₂ is subsequently implanted into the semiconductor substrate.

In practice, contact resistances have been checked in terms of several cases in which BF impurities or mixed BF₂ and B₁₁ impurities are implanted into a P+S/D (Source/Drain) area according to the present invention, and BF₂ impurities are implanted into a P+S/D area as being conventionally executed. As a result, as shown in FIG. 2, it has been established that the contact resistance (I) in the case in which BF impurities are implanted into the P+S/D (Source/Drain) area, and the contact resistance (II) in the case in which mixed BF₂ and B₁₁ impurities are implanted into the P+S/D area become lower than the contact resistance (III) in the case in which BF₂ impurities are implanted into the P+S/D area by 200 to 400 Ω.

Like this, if BF impurities or mixed BF₂ and B₁₁ impurities are employed as p-type impurities for use in ion implantation, it can be expected that contact resistance can be reduced and refresh and cell current properties can be enhanced.

In addition, if the inventive method for implanting ions as described above is applied to ion implantation into a cell area of a semiconductor, threshold voltage can be readily controlled; accordingly, it is possible to fabricate semiconductor devices which are superior in refresh and cell current properties. Moreover, if the method for implanting ions as described above is applied to ion implantation into a PMOS transistor, threshold voltage of such a PMOS transistor can be readily controlled; accordingly, it is possible to fabricate semiconductor devices which are superior in refresh and cell current properties. Furthermore, if the method for implanting ions as described above is applied to ion implantation into an NMOS transistor, threshold voltage of such an NMOS transistor can be readily controlled; accordingly, it is possible to fabricate semiconductor devices which are superior in refresh and cell current properties.

As described above, according to the present invention, refresh and cell current properties of semiconductor devices can be enhanced through ion implantation; accordingly it is possible to increase reliability of such semiconductor devices.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for implanting ions comprising steps of:
providing a semiconductor substrate; and
implanting BF impurities or mixed BF₂ and B₁₁ impurities into the semiconductor substrate.

2. A method as claimed in claim 1, wherein the BF impurities are implanted in a dosage of 1.0E11 to 1.0E16 dose/cm².

3. A method as claimed in claim 1, wherein the BF impurities are implanted with energy of 1 to 100 KeV.

4. A method as claimed in claim 1, wherein the mixed BF₂ and B₁₁ impurities are sequentially implanted, in an order of BF₂ first and B₁₁ second or in the order of B₁₁ first and BF₂ second, into the semiconductor substrate.

5. A method for fabricating a semiconductor device comprising steps of:
providing a semiconductor substrate; and
implanting BF impurities or mixed BF₂ and B₁₁ impurities into a cell area in the semiconductor substrate, thereby forming an area for controlling threshold voltage of the cell area.

6. A method as claimed in claim 5, wherein the BF impurities are implanted in a dosage of 1.0E11 to 1.0E16 dose/cm².

7. A method as claimed in claim 5, wherein the BF impurities are implanted with energy of 1 to 100 KeV.

8. A method for fabricating a semiconductor device comprising steps of:
providing a semiconductor substrate; and
implanting BF impurities or mixed BF₂ and B₁₁ impurities into a PMOS transistor area in the semiconductor substrate, thereby forming an area for controlling threshold voltage of the PMOS transistor.

9. A method as claimed in claim 8, wherein the BF impurities are implanted in a dosage of 1.0E11 to 1.0E16 dose/cm².

10. A method as claimed in claim 8, wherein the BF impurities are implanted with energy of 1 to 100 KeV.

11. A method for fabricating a semiconductor device comprising steps of:
providing a semiconductor substrate; and
implanting BF impurities or mixed BF₂ and B₁₁ impurities into an NMOS transistor area in the semiconductor substrate, thereby forming an area for controlling threshold voltage of the NMOS transistor.

12. A method as claimed in claim 11, wherein the BF impurities are implanted in a dosage of 1.0E11 to 1.0E16 dose/cm².

13. A method as claimed in claim 11, wherein the BF impurities are implanted with energy of 1 to 100 KeV.
